(19) United States
(12) Patent Application Publication
(10) Pub. No.: US 2009/0091894 A1
(43) Pub. Date: Apr. 9, 2009

(54) MULTICHIP MODULE

(76) Inventor: Shoji SAKURAI, Osaka (JP)

Correspondence Address: BIRCH STEWART KOLASCH & BIRCH, PO BOX 747, FALLS CHURCH, VA, 22040-0747, US

(21) Appl. No.: 12/233,346

(22) Filed: Sep. 18, 2008

(30) Foreign Application Priority Data
Oct. 3, 2007 (JP) 2007-260116

(51) Int. Cl. H05K 1/18

(52) U.S. Cl. 361/737

(57) ABSTRACT

Provided is a multichip module having a module substrate 2 on which an electronic component 3 is mounted, a conductor 8 electrically connected to a land 12 formed on the module substrate 2, a molding resin 6 covering the electronic component 3 and the conductor 8, and a conductive film 7 formed continuously on the molding resin 6 and the conductor 8 exposed from the molding resin 6.

This nonprovisional application claims priority under 35 U.S.C. §119(a) on Patent Application No. 2007-260116 filed in Japan on Oct. 3, 2007, the entire contents of which are hereby incorporated by reference.

### BACKGROUND OF THE INVENTION

1. Field of the Invention

The present invention relates to a multichip module that can seal in an electromagnetic wave generated by an electronic component.

2. Description of Related Art

Multichip modules having a module substrate on which a plurality of electronic components are mounted and covered with a shield are disclosed in JP-B-3941634 (pages 3 to 6 and FIG. 2; hereinafter referred to as “Patent Document 1”) and JP-A-2002-343923 (pages 8 to 15 and FIG. 1; hereinafter referred to as “Patent Document 2”). FIG. 3 is a side sectional view showing an outline of the multichip module described in Patent Document 1. A multichip module 20 has a module substrate 2 on which a plurality of electronic components 3 are mounted. The electronic components 3 are each built with a semiconductor chip or the like, and together form an electronic circuit.

A metal shield case 4 is attached to the module substrate 2 by solder 5 so as to cover the electronic components 3. The shield case 4 seals in an electromagnetic wave generated by the electronic components 3.

In the above multichip module 20, a land (not shown) is formed on the module substrate 2 for soldering the shield case 4 to the module substrate 2. Such a land requires a large area to ensure that the shield case 4 is firmly attached. In addition, there is a need to leave ample clearance between the electronic components 3 and the shield case 4 so as to prevent contact between them. This undesirably leads to an increase in size of the multichip module 1.

FIG. 4 is a side sectional view showing an outline of the multichip module described in Patent Document 2. In a multichip module 21, electronic components 3 formed on a module substrate 2 are encapsulated in a molding resin 6. On the 2 molding resin 6, a conductive film 7 made of metal or the like is formed. The conductive film 7 seals in an electromagnetic wave generated by the electronic components 3.

The above multichip module 21 eliminates the need for a land used for attachment of the shield case 4 (see FIG. 3). In addition, since the thickness of the molding resin 6 can be controlled with a high degree of accuracy by using vacuum printing or the like, it is possible to reduce clearance between the electronic component 3 and the conductive film 7. This makes miniaturization of the multichip module 21 possible.

However, the above multichip module 21 disclosed in Patent Document 2 suffers from an unstable potential because the conductive film 7 is not connected to the ground potential. This inconveniently makes it impossible to obtain sufficient shielding effectiveness.

### SUMMARY OF THE INVENTION

It is an object of the present invention to provide a multichip module that can achieve miniaturization and obtain improved shielding effectiveness.

To achieve the above object, according to one aspect of the present invention, a multichip module is provided with: a module substrate on which an electronic component is mounted; a conductor electrically connected to a land formed on the module substrate; a molding resin covering the electronic component and the conductor; and a conductive film formed continuously on the molding resin and the conductor exposed from the molding resin.

In this structure, the electronic component is mounted on the module substrate, and the module substrate is provided with the land formed as a conductive pattern. The conductor is, for example, soldered to the land so as to be electrically connected thereto. The electronic component and the conductor are encapsulated in the molding resin, such that the surface of the conductor is exposed from the molding resin. On the surface of the molding resin and the conductor exposed from the molding resin, the conductive film is continuously formed by plating or the like. As a result, the conductive film formed on the molding resin is made electrically continuous with the land, and the conductive film seals in an electromagnetic wave generated by the electronic component.

This makes it possible to maintain the conductive film at the ground potential by connecting the land to the ground potential. This helps stabilize the potential of the conductive film, and gives improved shielding effectiveness to the multichip module.

Since the thickness of the molding resin can be controlled with a high degree of accuracy, it is possible to reduce clearance between the electronic component and the conductive film. In addition, since the conductor connected to the land is held by the molding resin, it is possible to make smaller the area of the land. These factors make miniaturization of the multichip module possible.

Preferably, in the multichip module structured as described above, the conductor is made higher than the electronic component. This makes it easy to expose the conductor from the molding resin, and provide continuity between the conductor and the conductive film.

Preferably, the multichip module structured as described above is further provided with a trace formed on the module substrate, the trace being connected to the electronic component. Here, the land is formed independently of the trace.

With this structure, the electronic component is connected to the mother board or the like via the trace formed independently of the land, so as to receive a signal or the like. This makes it possible to ensure insulation between the conductive film and the trace and obtain stable shield effectiveness.

Preferably, in the multichip module structured as described above, the conductor includes a plurality of conductors provided around the electronic component. With this structure, the plurality of conductors provided around the electronic component seal in an electromagnetic wave generated by the electronic component. This makes it possible to further improve shielding effectiveness.

Preferably, in the multichip module structured as described above, the conductor is a solder ball. This makes it easy to connect the conductor to the land, and makes it possible to reduce cost of the multichip module.

Preferably, in the multichip module structured as described above, the module substrate is a multilayer wiring substrate. This helps form complicated and higher-density wiring in a smaller area, contributing to further miniaturization of the multichip module.

Preferably, in the multichip module structured as described above, the module substrate is a ceramic substrate. This makes it possible to obtain a highly-reliable multichip module with improved heat radiation.

Preferably, in the multichip module structured as described above, the module substrate is a resin substrate. This makes it possible to achieve high-density wiring, making further miniaturization of the multichip module possible.

Preferably, in the multichip module structured as described above, the electronic component is built with any one or any combination of a semiconductor chip, a resistor, an inductor, a capacitor, a crystal oscillator, and a filter. This makes it possible to use a thin electronic component, making the multichip module even thinner.

### BRIEF DESCRIPTION OF THE DRAWINGS

FIG. 1 a plan view showing a multichip module according to an embodiment of the invention;

FIG. 2 is a side sectional view showing the multichip module according to the embodiment of the invention;

FIG. 3 is a side sectional view showing a conventional multichip module; and

FIG. 4 is a side sectional view showing a conventional multichip module.

### DETAILED DESCRIPTION OF PREFERRED EMBODIMENTS

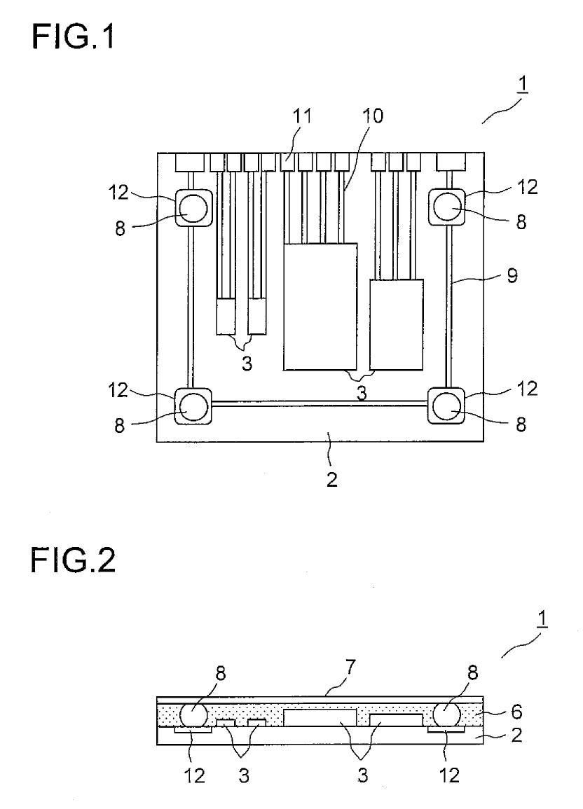

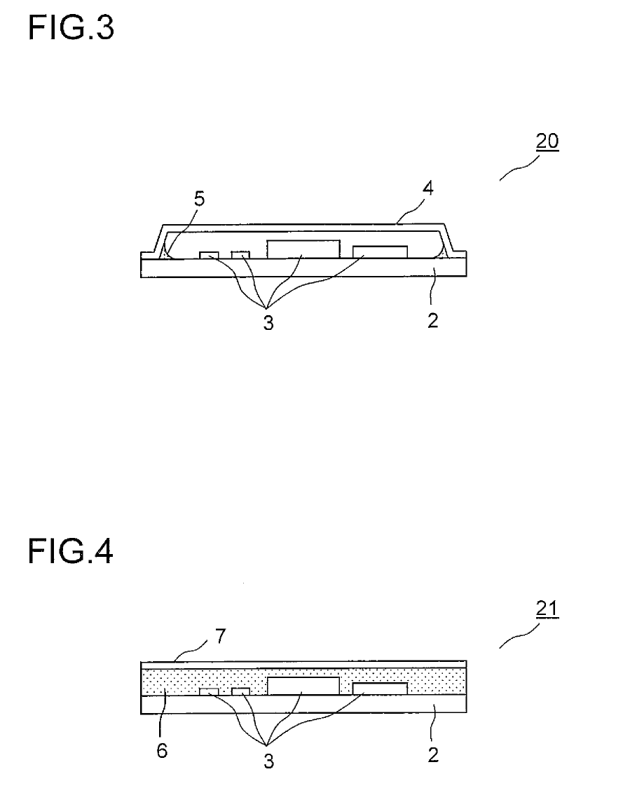

Hereinafter, embodiments of the invention will be described with reference to the accompanying drawings. FIGS. 1 and 2 are a plan view and a side sectional view, respectively, showing a multichip module of an embodiment. For convenience's sake, in these figures, such parts as are found also in the above-described conventional examples shown in FIGS. 3 and 4 will be identified with common reference numerals. A multichip module 1 has a module substrate 2 on which a plurality of electronic components 3 are mounted.

The module substrate 2 is formed as a ceramic substrate or a resin substrate. The ceramic substrate has a low rate of thermal expansion, has high heat radiation, and provides excellent electrical insulation. As a result, by forming the module substrate 2 as a ceramic substrate, it is possible to provide a multichip module 1 with improved heat radiation. In addition, doing so helps reduce expansion and contraction and insulation breakdown caused by heat generated by the electronic components 3, making it possible to achieve a highly-reliable multichip module 1.

On the other hand, forming the module substrate 2 as a resin substrate makes it possible to achieve high-density wiring. This allows chips to be mounted by using flip-chip implementation, making miniaturization of the multichip module 1 possible. Moreover, it is further preferable that the module substrate 2 be formed as a multilayer wiring substrate. Doing so helps form complicated and higher-density wiring in a smaller area. This contributes to further miniaturization of the multichip module 1.

The electronic components 3 are each built with any one or any combination of a semiconductor chip, a resistor, an inductor, a capacitor, a crystal oscillator, and a filter, and together form an electronic circuit. These electronic components 3 can be made thinner. Using these thin electronic components 3 makes it possible to make the multichip module 1 even thinner.

The module substrate 2 has traces 9 and 10 formed thereon. The traces 9 and 10 each have a connector portion 11 at the edge of the module substrate 2, the connector portion 11 being connected to a mother board or the like via a connector (not shown) or the like. The electronic components 3 are connected to the traces 10. The traces 10 are each connected to the mother board or the like via the connector portion 11 for receiving power or a signal to each electronic component 3.

On the trace 9 formed independently of the traces 10, a plurality of lands 12 are formed. The trace 9 is connected to the ground potential of the mother board or the like via the connector portions 11.

Conductors 8 made of metal or the like are, for example, soldered to the lands 12 so as to be electrically connected thereto. The use of a solder ball as the conductor 8 makes it easy to achieve solder connection, and its versatility and low price contributes to reduction of cost of the multichip module 1. The electronic components 3 and the conductors 8 are encapsulated in a molding resin 6 by vacuum printing or the like. The conductors 8 are made higher than the electronic components 3, and the molding resin 6 is formed so that the upper face of each conductor 8 is exposed from it.

On the molding resin 6 and the conductors 8 exposed from the molding resin 6, a conductive film 7 made of metal or the like is formed continuously by plating, vapor deposition, or the like. As a result, the conductive film 7 formed on the molding resin 6 is made electrically continuous with the lands 12 via the conductors 8.

In the multichip module 1 structured as described above, the trace 9 is connected to the ground potential of the mother board or the like, and the lands 12, the conductors 8, and the conductive film 7 are maintained at the ground potential. This makes it possible to seal in an electromagnetic wave generated by the electronic components 3 with the conductive film 7 at the ground potential.

According to this embodiment, since the conductive film 7 formed on the molding resin 6 covering the electronic components 3 is formed continuously on the conductors 8 that are electrically continuous with the lands 12, it is possible to maintain the conductive film 7 at the ground potential by connecting the lands 12 to the ground potential. This helps stabilize the potential of the conductive film 7, and gives improved shielding effectiveness to the multichip module 1.

Since the thickness of the molding resin 6 can be controlled with a high degree of accuracy by using vacuum printing or the like, it is possible to reduce clearance between the electronic components 3 and the conductive film 7. In addition, since the conductors 8 connected to the lands 12 are held by the molding resin 6, it is possible to make smaller the area of the lands 12. These factors make miniaturization of the multichip module I possible.

It is to be noted that the conductors 8 may be made lower than the electronic components 3 as long as the upper surface thereof is exposed from the molding resin 6. However, making the conductors 8 higher than the electronic components 3 as in this embodiment makes it easy to expose the conductors 8 from the molding resin 6, and provide continuity between the conductors 8 and the conductive film 7.

Moreover, as a result of the lands 12 and the trace 9 being formed independently of the traces 10 connected to the electronic components 3, it is possible to ensure insulation between the conductive film 7 and the traces 10 and obtain stable shield effectiveness.

In this embodiment, it is possible to maintain the conductors 8 at the same potential via the conductive film 7 as long as at least one of the lands 12 connected to the conductors 8 is connected to the ground potential of the mother board or the like. In a case where an electronic component 3 that generates a strong electromagnetic wave is mounted, it is simply necessary to provide a plurality of conductors 8 in such a way as to surround that electronic component 3. This makes it possible to further improve shielding effectiveness.

The present invention can be applied to multichip modules that can seal in an electromagnetic wave generated by an electronic component.

What is claimed is:

1. A multichip module comprising:
a module substrate on which an electronic component is mounted;
a conductor electrically connected to a land formed on the module substrate;
a molding resin covering the electronic component and the conductor; and
a conductive film formed continuously on the molding resin and the conductor exposed from the molding resin.

2. The multichip module of claim 1,
wherein the conductor is made higher than the electronic component.

3. The multichip module of claim 1, further comprising:
a trace formed on the module substrate, the trace being connected to the electronic component,
wherein the land is formed independently of the trace.

4. The multichip module of claim 1,
wherein the conductor comprises a plurality of conductors provided around the electronic component.

5. The multichip module of claim 1,
wherein the conductor is a solder ball.

6. The multichip module of claim 1,
wherein the module substrate is a multilayer wiring substrate.

7. The multichip module of claim 1,
wherein the module substrate is a ceramic substrate.

8. The multichip module of claim 11
wherein the module substrate is a resin substrate.

9. The multichip module of claim 1,
wherein the electronic component is built with any one or any combination of a semiconductor chip, a resistor, an inductor, a capacitor, a crystal oscillator, and a filter.
